(19) United States
(12) Patent Application Publication
(10) Pub. No.: US 2010/0214713 A1
(43) Pub. Date: Aug. 26, 2010

(54) LAMINATE SHEET FOR ELECTROMAGNETIC RADIATION SHIELDING AND GROUNDING

(75) Inventor: Jin-Ho Song, Goyang-si (KR)

Correspondence Address: SUGHRUE MION, PLLC, 2100 PENNSYLVANIA AVENUE, N.W., SUITE 800, WASHINGTON, DC, 20037, US

(73) Assignee: Nano Interface Technology, Siheung-si (KR)

(21) Appl. No.: 12/597,343

(22) PCT Filed: Apr. 24, 2008
(86) PCT No.: PCT/KR08/02324

§ 371 Date: Apr. 26, 2010

(30) Foreign Application Priority Data
Apr. 24, 2007 (KR) 10-2007-0039793
Nov. 1, 2007 (KR) 10-2007-0110817
Apr. 14, 2008 (KR) 20-2008-0004890

(51) Int. Cl. H05F 3/00; H05K 9/00

(52) U.S. Cl. 361/220; 174/388; 174/358

(57) ABSTRACT

Disclosed is a laminate sheet including a polymer resin layer; and at least one metal foil layer laminated on one surface or both surfaces of the polymer resin layer, which is applied to shield electromagnetic waves, and/or to ground static electricity.

### TECHNICAL FIELD

The present invention relates to a laminate sheet for grounding static electricity and/or shielding electromagnetic waves.

### BACKGROUND ART

As an electronic/communication device has been recently lightened, miniaturized, and varied, electronic components have become multi-functional, and thus have a complicated structure. Due to such a complicated internal structure, and various components existing in a certain space, the components electronically and electrically interact with each other. Also, an electronic·electromagnetic waves (hereinafter, referred to as ‘electromagnetic waves’) generated from the electronic/communication device disturbs the functions of peripheral devices, and causes problems such as performance degradation, noise, image deterioration, lifetime reduction, etc.

In addition, as an electronic/communication device has become miniaturized and highly integrated, tolerance of the electronic/communication device to static electricity generated by friction, peeling, contact, etc. has been reduced. For example, transient voltage may be generated by electrostatic discharge (ESD), which may easily damage or deteriorate the electronic/communication device. Also, dust may be attached on components of the electronic/communication device by static electricity, and thus may pollute the electronic/communication device, thereby causing performance degradation of the electronic/communication device.

As a material for shielding electromagnetic waves or grounding static electricity causing such problems, a metal foil, such as an aluminum foil, has been used. The metal foil can allow the static electricity to flow to a ground wire due to high electrical conductivity, and also can eliminate or compensate the electromagnetic waves.

However, the metal foil is easily bent and partially folded due to its thin thickness, thereby degrading the operation efficiency of an operator. Also, due to insufficiency of elasticity or flexibility, the metal foil has poor conformal adhesive property with a portion having various shapes and curves, and thus cannot efficiently shield the electromagnetic waves and cannot efficiently ground the static electricity to a ground wire. In addition, the metal foil is subjected to damage by a screw-fastening portion, etc., and is difficult to apply to an automated assembly line due to insufficiency of tensile strength.

Instead of such a metal foil, metal coated or electroless plated electrically conductive fabric been used. When such a electrically conductive fabric is applied to an electronic/communication device, decrease of process efficiency is not occurred due crease of fabric folding unlike a metal foil.

However, as compared to the metal foil, the electrically conductive fabric has high surface resistance, and thus has low electrical conductivity, thereby having lower electromagnetic waves shielding property or a static electricity grounding property. Also, under high temperatures and high humidity, the electrically conductive fabric is decreasing electrical conductivity and rapidly oxidized, thereby reducing the electromagnetic wave shielding property or the static electricity grounding property. In addition, minute spaces between yarns of the fabrics and fibers of the yarns increase electrical resistance, thereby reducing the electromagnetic wave shielding property or the static electricity grounding property. Also, it is difficult to efficiently shield electromagnetic waves or ground static electricity because minute dust or moisture absorbed in minute spaces of the fabrics disturb electrical current flow.

### DISCLOSURE

### Technical Problem

Therefore, the present invention has been made to solve the above-mentioned problems. We have found that a metal foil layer is laminated with a polymer resin layer, and thus, it is possible to reinforce the tensile strength of the metal foil layer, and increase the flexibility of the metal foil layer.

It is an object of the present invention to provide a laminate sheet including a metal foil layer laminated on a polymer resin layer which can improve the process efficiency of the worker and the conformal adhesive property with an electronic/communication device.

### Technical Solution

In accordance with an aspect of the present invention, there is provided a laminate sheet including a polymer resin layer; and at least one metal foil layer laminated on one surface or both surfaces of the polymer resin layer, which is applied to shield electromagnetic waves, and/or to ground static electricity.

In accordance with another aspect of the present invention, there is provided a tape including the aforementioned laminate sheet; and an adhesive layer partially or entirely laminated on one surface of the laminate sheet, which is applied to shield electromagnetic waves and/or to ground static electricity to a ground wire.

In accordance with a further aspect of the present invention, there is provided a gasket including an elastomer core; and the aforementioned laminate sheet surrounding an outer circumferential surface of the elestomer core, which is applied to shield electromagnetic waves and/or to ground static electricity to a ground wire.

### Advantageous Effects

In the present invention, since a metal foil layer is laminated on one surface or both surfaces of a polymer resin layer, the tensile strength of the metal foil layer is reinforced, and the flexibility of the metal foil layer is increased. Accordingly, the process efficiency of the workers and the conformal adhesive property with an electronic/communication device are improved, and thus it is possible to efficiently protect the electronic/communication device from electromagnetic waves and/or static electricity.

### BRIEF DESCRIPTION OF THE DRAWINGS

FIG. 1 is a cross-sectional view illustrating a laminate sheet according to an embodiment of the present invention.

FIG. 2 is a cross-sectional view illustrating a laminate sheet according to another embodiment of the present invention, wherein an enlarged portion illustrates an embossed portion formed on the laminate sheet of the present invention.

FIG. 3 is a perspective view illustrating a laminate sheet according to another embodiment of the present invention, wherein an enlarged portion illustrates an embossed portion formed on the laminate sheet of the present invention.

FIG. 4 is a cross-sectional view illustrating a laminate sheet according to a further embodiment of the present invention.

FIG. 5 is a cross-sectional view illustrating a laminate sheet according to a still further embodiment of the present invention, wherein an enlarged portion illustrates a perforated portion formed on the laminate sheet of the present invention.

FIG. 6 is a perspective view illustrating a laminate sheet according to a still further embodiment of the present invention, wherein an enlarged portion illustrates a perforated portion formed on the laminate sheet of the present invention.

FIG. 7 is a cross-sectional view illustrating a tape including a laminate sheet according to the present invention.

FIG. 8 is a cross-sectional view illustrating a gasket including a laminate sheet according to the present invention.

<Brief Description of the Indication>

| 10: laminated sheet, 20: tape, 30: gasket, | |
|---|---|
| 1: polymer resin layer, | 2: metal foil layer, |
| 3: embossed portion, | 4: perforated portion, |
| 5: adhesive layer, | 6: elastomer core |

### BEST MODE

### Mode for Invention

Hereinafter, exemplary embodiments of the present invention will be described with reference to the accompanying drawings.

In the present invention, electromagnetic waves indicate electron waves and electromagnetic waves.

In general, a metal foil such as an aluminum foil has low surface (electrical) resistance, and thus is used for an electronic/communication device so as to shield electromagnetic waves and/or ground static electricity. Such a metal foil is easily bent and partially folded by an external force due to its thin thickness. Thus, when the metal foil is applied to the electronic/communication device, the process efficiency of the workers are decreased, and also the conformal adhesive property with the electronic/communication device is lowered, thereby impair an electromagnetic wave shielding property and/or a static electricity grounding property.

Accordingly, in the present invention, a metal foil layer 2 is laminated with a polymer resin layer 1, and thus, the tensile strength of the metal foil layer is reinforced by the polymer resin layer, and the bending or partial folding of the metal foil layer may be suppressed by the polymer resin layer. Thus, it is possible to improve the process efficiency of the workers, and the conformal adhesive property with an electronic/communication device.

Specifically, in the present invention, a polymer resin of the polymer resin layer is diffused inside of the surface of the metal foil layer, or is bonded on the surface of the metal foil layer. When the metal foil layer is partially folded by an external force, a portion of the polymer resin layer being in contact with a folded portion of the metal foil layer, together with the metal foil layer, is folded, but since a folded portion of the polymer resin layer has enough elasticity or flexibility, the polymer resin layer is restored to its original state. Herein, the metal foil layer is also restored to its original state. Also, stiffness of the metal foil layer may be reduced by the polymer resin layer. Accordingly, when a laminate sheet according to the present invention is applied to an electronic/communication device, processing efficiency of the workers may be improved. Also, the laminate sheet according to the present invention may improve the conformal adhesive property with the electronic/communication device, regardless of the curve or shape of a contact portion. Furthermore, the tensile strength of the metal foil layer is reinforced by the polymer resin layer, which provides the laminate sheet of the present invention to be fabricated on an automated assembly line, and to be applied to an electronic/communication device.

Therefore, the laminate sheet of the present invention can efficiently shield electromagnetic waves generated from an electronic/communication device, and/or can efficiently ground static electricity to the outside such as a ground wire, thereby protecting the electronic/communication device from the electromagnetic waves and/or the static electricity.

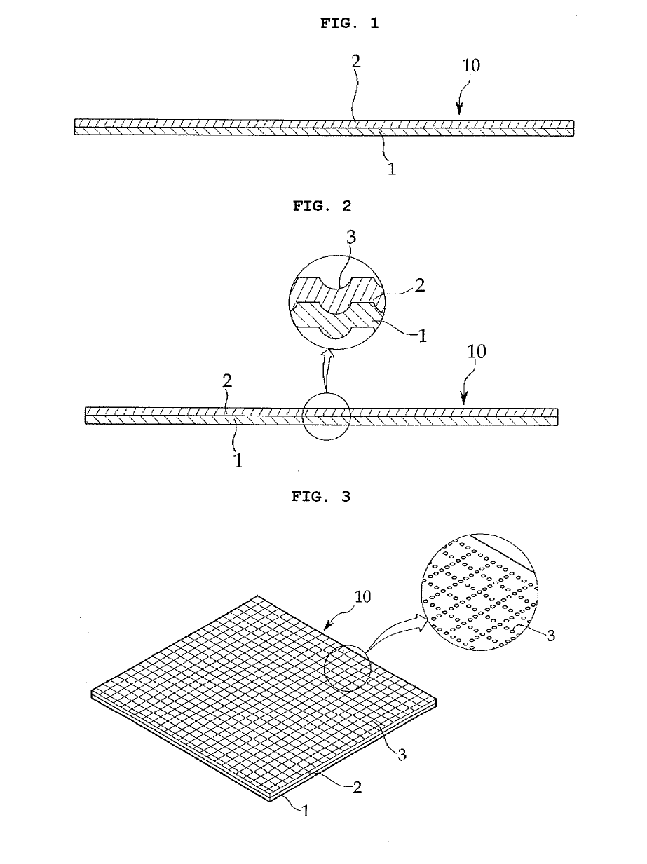

According to an embodiment of the present invention, a laminate sheet 10 includes: a polymer resin layer 1; and at least one metal foil layer 2 laminated on one surface or both surfaces of the polymer resin layer (see FIG. 1).

In the present invention, a material forming the metal foil layer 2 is not particularly limited, as long as the material has high electrical conductivity. Examples of the material include, but are not limited to, gold, platinum, silver, copper, nickel, tin, aluminum, and an alloy thereof. According to an embodiment of the present invention, the metal foil layer may be a thin aluminum foil. Due to the metal foil layer made from such a material, the surface resistance of the laminate sheet according to the present invention may be about 10⁻⁵ to 10⁻⁸ Ω·m at 20° C. Therefore, the laminate sheet of the present invention can shield electromagnetic waves and/or can ground static electricity to the outside, and thus can protect an electronic/communication device from the electromagnetic waves and/or the static electricity.

The metal foil layer made from such a material may be formed in at least one layer, for example, 2 to 5 layers. Herein, respective layers may include the same or different materials, or otherwise, layers including the same materials may be sequentially formed.

The thickness of the metal foil layer may vary according to an electronic/communication device where the laminate sheet of the present invention is applied, and is within a range of about 2 to 200 μm, preferably of about 5 to 80 μm. If the thickness of the metal foil layer is greater than 200 μm, the weight of the final laminate sheet is increased, which is not appropriate for an electronic/communication device having a tendency to be light. Also, if the thickness of the metal foil layer is less than 2 μm, the laminate sheet applied to the electronic/communication device may be easily torn.

Also, a material forming the polymer resin layer 1 is not particularly limited, as long as the material is a polymer resin having elasticity or flexibility. However, it is preferable that the polymer resin has an average molecular weight of about 5,000 to 1,000,000.

The polymer resin may be made from a thermoplastic resin or a thermosetting resin. Specifically, examples of the polymer resin include, but are not limited to, polyethylene, polypropylene, polyethylene terephthalate, polycarbonate, polyvinyl acetal, polyvinyl butyral, polyvinylcarbazole, polyurethane, polyester, ethylene vinyl acetate, an epoxy resin, an acrylic resin, polyvinyl chloride, polyvinylidene chloride, a fluoro-based resin, a silicon-based resin, etc. and also, a styrene-acrylonitrile copolymer, an ethylene-vinyl alcohol copolymer, an acrylonitrile-butadiene-styrene resin, etc.

The thickness of the polymer resin layer made from such a polymer resin is preferably adjusted according to the thickness of the metal foil layer, the kind of material forming the metal foil layer, etc. If the thickness of the polymer resin layer is too thin, it is impossible to desirably prevent the metal foil layer from being folded. Accordingly, the thickness of the polymer resin layer is within a range of about 2 to 200 μm, preferably of about 5 to 100 μm, and more preferably of about 10 to 50 μm.

In the present invention, the polymer resin layer may further include an antistatic agent and/or an electromagnetic wave absorber, in addition to the aforementioned polymer resin. Herein, since the antistatic agent is further included in the polymer resin layer, the laminate sheet of the present invention can suppress the generation of static electricity, thereby more efficiently protecting an electronic/communication device from the static electricity. Also, since the electromagnetic wave absorber is further included in the polymer resin layer, the laminate sheet of the present invention can absorb electromagnetic waves, thereby more efficiently protecting the electronic/communication device from the electromagnetic waves.

In the present invention, the antistatic agent is not particularly limited, as long as it is known in the art that the material has an antistatic property. Examples of such an antistatic agent include a surfactant, etc.

Specifically, the surfactant is classified into anionic, cationic, amphoteric, and non-ionic surfactants. Examples of the anionic surfactant include alkylsulfonate, alkylsulfate, alkylphosphite, sodium alkylsulfonate, etc.; examples of the cationic surfactant include a quaternary ammonium compound, etc.; examples of the amphoteric surfactant include alkylbetain, alkylalanine, etc.; and examples of the non-ionic surfactant include ethoxylated alkylamine, fatty acid ester, glyceride alkylamine, polyethylene glycol ester, etc.

The content of the antistatic agent is not particularly limited. However, if the antistatic agent is used in an excessive amount, the antistatic agent may be not uniformly dispersed inside of the polymer resin, thereby causing the non-uniformity of the surface resistance of a sheet. Therefore, the antistatic agent may be used in an amount of about 1 to 100 parts by weight based on 100 parts by weight of the polymer resin.

Also, in the present invention, there is no particular limitation to the material that may be used as the electromagnetic wave absorber, as long as it is a material capable of absorbing electromagnetic waves. Non-limiting examples of such an electromagnetic wave absorber include iron oxide, magnesium oxide, zinc oxide, copper oxide, magnesium-zinc-based ferrite, nickel-zinc-based ferrite, etc.

The content of the electromagnetic wave absorber is not particularly limited. However, if the electromagnetic wave absorber is used in an excessive amount, the electromagnetic wave absorber may be not uniformly dispersed inside of the polymer resin, thereby causing the non-uniformity of the electromagnetic wave absorbing capacity of a final laminate sheet. Therefore, the electromagnetic wave absorber may be used in an amount of about 1 to 300 parts by weight, preferably of about 1 to 200 parts by weight, based on 100 parts by weight of the polymer resin.

Meanwhile, FIGS. 2 and 3 show a laminate sheet 10 according to another embodiment of the present invention. A sheet where a metal foil layer 2 is laminated on a polymer resin layer 1 includes multiple embossed portions 3 formed at a predetermined interval on one surface or both surfaces thereof. Since the embossed portions 3 are formed on the laminate sheet of the present invention, creases generated by stress by the use of the laminate sheet according to the present invention are formed along the embossed portions, and thus formation of non-uniform creases may be reduced. Also, due to the embossed portions, the laminate sheet according to the present invention may improve the conformal adhesive property with an electronic/communication device, regardless of the curve or shape of a contact portion. In addition, the embossed portions increase a specific surface area of the metal foil layer, thereby increasing a static electricity grounding effect and an electromagnetic wave shielding effect.

The interval between the embossed portions 3, and the disposed angle and distribution ratio of the embossed portions may be variously adjusted according to an electronic/communication device where the laminate sheet of the present invention is applied. The embossed portions 3 may be preferably formed in a proportion of about 1 to 100 per 1 cm², and herein, an angle between each of a series of embossed portions and its closest embossed portion disposed on an adjacent row may be about 30 to 90°, or about 45 to 60° in certain circumstances. According to such a distribution ratio, and a disposed angle of the embossed portions, the interval between one embossed portion and the adjacent embossed portion may be within a range of about 10 μm to 5 mm, preferably of about 20 μm to 1 mm.

Also, the shape and depth of the embossed portions are not particularly limited, and may be variously adjusted according to the thickness of the laminate sheet of the present invention, and an electronic/communication device where the laminate sheet is applied. The shape of the embossed portions includes a concave/convex hemisphere shape, a concave/convex quadrangle, an engraved/embossed texture pattern, etc. However, the scope of the present invention is not limited thereto. Also, the depth of the embossed portions may be in the range of about 5 μm to 1 mm, but, may be adjusted according to the thickness of the metal foil layer.

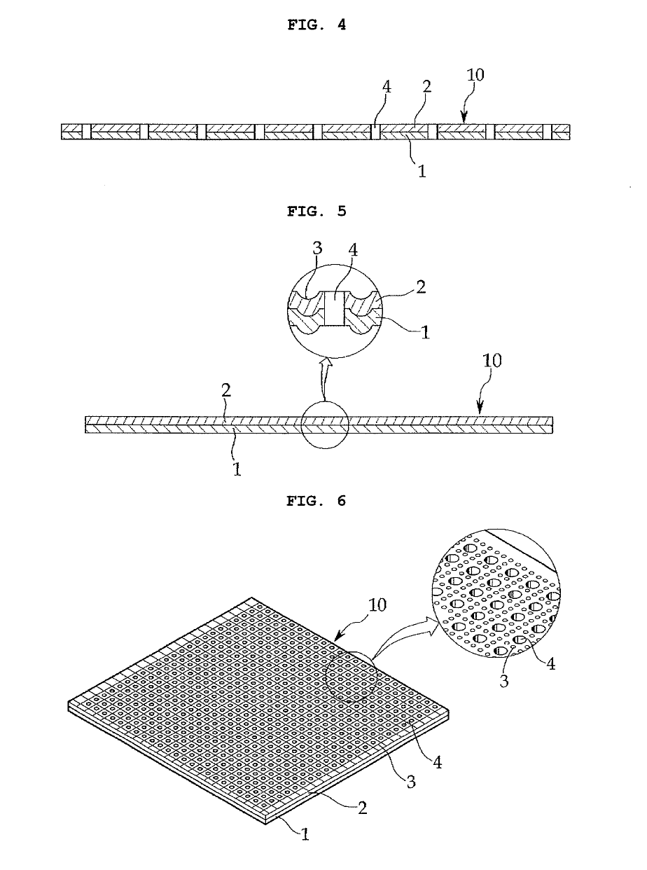

Meanwhile, as shown in FIG. 4, in a laminate sheet 10 of the present invention, multiple perforated portions 4 penetrated in a thickness direction of the laminate sheet may be formed. Accordingly, since the perforated portions 4 are further formed in the laminate sheet, the stress generated by the application of the laminate sheet to an electronic/communication device may be dispersed. Thus, on the laminate sheet of the present invention, the creases by the stress may be reduced. Also, the further formation of the perforated portions 4 in the laminate sheet may improve flexibility of a final laminate sheet. Thus, the laminate sheet according to the present invention may have an improved conformal adhesive property with an electronic/communication device, thereby increasing electromagnetic wave shielding efficiency and/or static electricity grounding efficiency.

The diameter of the perforated portions is adjusted according to the position of an electronic/communication device where the laminate sheet of the present invention is applied, and is preferably within a range of about 10 μm to 5 mm.

Also, the distribution ratio and interval of the perforated portions are preferably within a range such that the static electricity grounding efficiency and/or the electromagnetic wave shielding efficiency are/is not reduced. For example, the perforated portions may be formed in a proportion of about 1 to 100 per 1 cm². Also, an angle between each of a series of perforated portions and its closest perforated portion disposed on an adjacent row may be about 30 to 90°, or about 45 to 60° in certain circumstances.

In the case of a laminate sheet including perforated portions formed therein, the whole area occupied by the perforated portions is in the range of about 10 to 50%, preferably of about 20 to 40%, based on the surface area of the laminate sheet. If the area occupied by the perforated portions is increased, the surface area of the metal foil layer may be decreased, thereby reducing the electromagnetic wave shielding efficiency and/or the static electricity grounding efficiency.

Meanwhile, as shown in FIGS. 5 and 6, in a laminate sheet 10 including a polymer resin layer 1 and a metal foil layer 2, multiple embossed portions 3 are formed at a predetermined interval, and multiple perforated portions 4 penetrated in a thickness direction of the laminate sheet are formed between the embossed portions 3. Since the embossed portions 3 and the perforated portions 4 are formed in the laminate sheet, the laminate sheet of the present invention may have flexibility similar to a fabric. In other words, the laminate sheet of the present invention may be formed as a so-called metal fabric type.

Herein, the diameter of the perforated portions is preferably adjusted according to the interval of the embossed portions. According to the present invention, the diameter of the perforated portions may be within a range of about 10 μm to 5 mm.

Also, each of the perforated portions may be positioned in the space between one embossed portion and another embossed portion, or else, as shown in FIG. 6, may be positioned in the space between a series of embossed portions and another series of embossed portions.

However, as mentioned above, the increase in the area occupied by the perforated portions may decrease the surface area of the metal foil layer, thereby reducing the electromagnetic wave shielding efficiency and/or the static electricity grounding efficiency. Thus, the perforated portions are preferably formed in a proportion of about 1 to 100 per 1 cm².

Hereinafter, a method of fabricating a laminate sheet of the present invention, which can be applied to shield electromagnetic waves, and/or to ground static electricity, will be explained.

According to an embodiment of the present invention, the laminate sheet may be fabricated by the steps of: forming a metal foil layer 1; forming a polymer resin layer 2 by applying uncured or semi-cured polymer resin syrup on the metal foil layer; and curing the polymer resin layer. Herein, the method may further include the step of laminating another metal foil layer on one surface of the polymer resin layer, which is opposite to a polymer resin layer surface having the metal foil layer laminated thereon, before the step of curing the polymer resin layer. Otherwise, the method may further include the step of laminating another metal foil layer on one surface of the polymer resin layer, which is opposite to a polymer resin layer surface having the metal foil layer laminated thereon, by an adhesive means, such as an adhesive agent, etc. after the step of curing the polymer resin layer.

In the case of the fabrication method, uncured or semi-cured polymer resin syrup may be diffused into the space between metal particles of the metal foil layer. When the curing step is completed, bonds between the metal particles and the polymer resin are formed by the diffused materials, thereby allowing the polymer resin layer to be laminated on the metal foil layer. Accordingly, even if the metal foil layer is folded by the action of an external force, the polymer resin layer folded together with the metal foil layer can be restored to its original state due to elasticity or flexibility, and thus the metal foil layer can be restored to its original state. In other words, it is possible to suppress the folding of the metal foil layer. Also, even if the laminate sheet fabricated by the method is subjected to an external force, the metal foil layer and the polymer resin layer are not separated from each other.

A method of curing the uncured or semi-cured polymer resin layer may include a method known in the art, such as thermal curing, ultraviolet curing, etc. The properties of the laminate sheet of the present invention may depend on the curing method. Therefore, it is preferable to select the curing method in consideration of the kind of electronic/communication device where the laminate sheet of the present invention is applied, and required physical properties.

According to another embodiment of the present invention, a laminate sheet may be fabricated by the steps of: forming a metal foil layer by a metal material; forming a polymer resin layer; and laminating the metal foil layer on one surface or both surfaces of the polymer resin layer. Preferably, the method may further include the step of forming a primer layer on the polymer resin layer or on the metal foil layer, before the step of laminating the metal foil layer on the polymer resin layer. However, it is no matter which one of step of forming the metal foil layer and the step of forming the polymer resin layer is firstly carried out.

The step of forming the polymer resin layer is performed by applying uncured or semi-cured polymer resin syrup on a release sheet, and subjecting the syrup to curing. However, the scope of the present invention is not limited thereto. Herein, the formed polymer resin layer, before cured, may be laminated with the metal foil layer.

In the prepared polymer resin syrup, an antistatic agent and/or an electromagnetic wave absorber may be added.

Examples of the release sheet include a plastic release film such as a polyester terephthalate (PET) release film, release paper, non-woven fabric, glass, metal, etc.

Also, the step of forming the primer layer is improving the interlayer adhesive property between the polymer resin layer and the metal foil layer. The primer layer may be formed on the metal foil layer by roll coating, or die coating, etc., known method in the art. The primer layer may include a low molecular weight polymer resin having multiple functional groups. For example, a polyurethane-based resin, a polyacrylate-based resin, a polyolefin chloride-based resin, or a polyamide-based resin may be coated on the metal foil layer, as the primer layer. The primer layer formed by such a polymer resin can suppress the partial folding of the metal foil layer in the same manner of the polymer resin layer.

The step of laminating the metal foil layer on the polymer resin layer may be performed by a laminating method known in the art. Examples of the laminating method may include a method of heat-fusing a polymer resin layer and a metal foil layer by using a pre-heated press roller, a method of adhering a polymer resin layer to a metal foil layer by using an adhesive, etc. However, the scope of the present invention is not limited thereto.

Meanwhile, the above described fabrication method may further include the step of forming embossed portions 3 in the laminate sheet including the polymer resin layer and the metal foil layer by using an embossing roller. The embossing roller has various convex-shaped embossed portions formed on the surface thereof. If the embossed portions 3 are formed on only one surface of the laminate sheet, a rubber roller having a flat surface, together with the embossing roller, is used. On the other hand, if the embossed portions 3 are formed on both surfaces of the laminate sheet, a couple of embossing rollers are used. The embossed portions formed as described above can suppress the occurrence of non-uniform creases on the metal foil layer, and can improve the conformal adhesive property with an electronic/communication device. Also, since pressure is added by the formation of the embossed portions, the polymer resin layer and the metal foil layer can be more firmly laminated to each other, and thus are not easily separated by external forces.

When the embossed portions are formed by the embossing roller, the embossing roller may be preheated to a thermal deformation temperature of a thermoplastic resin, for example, to a temperature ranging from about 100 to about 200° C. Accordingly, even if the pressure added by the embossing roller is low, the embossed portions may be easily formed in the laminate sheet.

Also, the aforementioned fabrication method may further include the step of forming perforated portions 4 penetrated in a thickness direction of the laminate sheet including the polymer resin layer and the metal foil layer. Herein, a punching machine known in the art, such as a punching press, may be used. Preferably, a punching machine mounted with a pin, such as a micro-sized pin, is used to easily form minute perforated portions.

The laminate sheet of the present invention as fabricated above may be applied to shield electromagnetic waves, and/or to ground static electricity. Accordingly, an electronic/communication device may be protected from the electromagnetic waves and/or the static electricity, by the laminate sheet of the present invention.

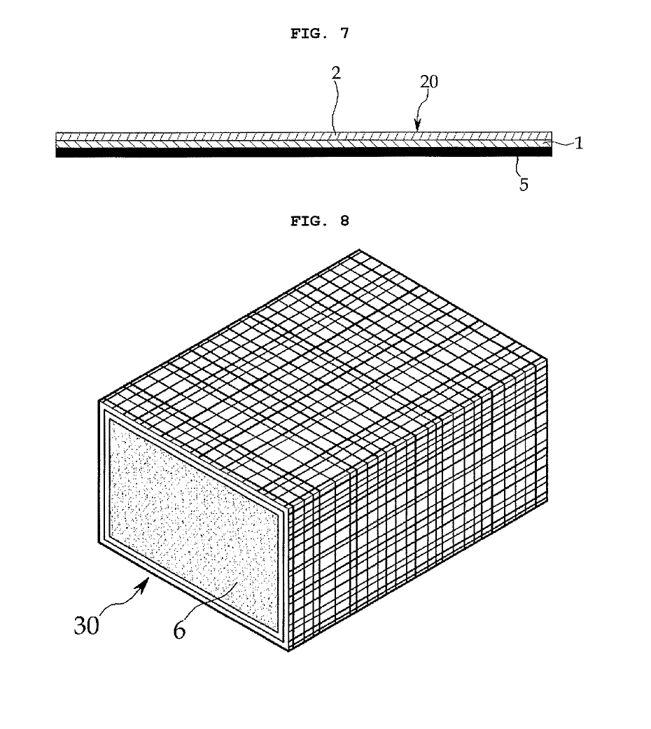

Meanwhile, it is possible to use the laminate sheet according to the present invention as a tape for shielding electromagnetic waves and/or grounding static electricity, by partially or entirely forming an adhesive layer 5 on the surface of the laminate sheet (see FIG. 7). Such a tape may be easily fixed on an electronic/communication device, and thus has high electromagnetic wave shielding efficiency and/or static electricity grounding efficiency.

A material forming the adhesive layer is not particularly limited, as long as the material is used as an adhesive in the art. However, an electrically conductive adhesive is preferred. The thickness of the adhesive layer is adjusted according to an electronic/communication device where the tape is applied, for example, in a range of about 5 to 100 μm. Also, the laminate sheet according to the present invention may be used for a gasket for shielding electromagnetic waves and/or grounding static electricity, in which the laminate sheet surrounds the whole surfaces (top, bottom, left, and right surfaces) of an elastomer core such as polyurethane foam, etc. (see FIG. 8).

The electronic/communication device where the laminate sheet of the present invention is applied includes a portable electronic/communication device such as a notebook computer, a PDA, a cellular phone, etc., and a battery used for them.

Although several exemplary embodiments of the present invention have been described for illustrative purposes, those skilled in the art will appreciate that various modifications, additions and substitutions are possible, without departing from the scope and spirit of the invention as disclosed in the accompanying claims.

1.-20. (canceled)

21. A laminate sheet for shielding electromagnetic waves, and/or to ground static electricity comprising a polymer resin layer; and at least one metal foil layer laminated on one surface or both surfaces of the polymer resin layer.

22. The laminate sheet as claimed in claim 21, wherein multiple embossed portions are formed on one surface or both surfaces of the laminate sheet.

23. The laminate sheet as claimed in claim 21, wherein multiple perforated portions penetrated in a thickness direction of the laminate sheet are formed.

24. The laminate sheet as claimed in claim 22, wherein multiple perforated portions are formed, the multiple perforated portions being positioned between the embossed portions and being penetrated in a thickness direction of the laminate sheet.

25. The laminate sheet as claimed in claim 23, wherein an area occupied by the perforated portions is within a range of 10 to 50%, based on a surface area of the laminate sheet.

26. The laminate sheet as claimed in claim 24, wherein an area occupied by the perforated portions is within a range of 10 to 50%, based on a surface area of the laminate sheet.

27. The laminate sheet as claimed in claim 21, wherein the polymer resin layer further comprises at least one of an antistatic agent and an electromagnetic wave absorber.

28. The laminate sheet as claimed in claim 27, wherein the antistatic agent is selected from the group including an anionic surfactant, a cationic surfactant, an amphoteric surfactant, and a non-ionic surfactant.

29. The laminate sheet as claimed in claim 27, wherein the antistatic agent is used in an amount of 1 to 100 parts by weight based on 100 parts by weight of a polymer resin of the polymer resin layer.

30. The laminate sheet as claimed in claim 27, wherein the electromagnetic wave absorber is selected from the group including iron oxide, magnesium oxide, zinc oxide, copper oxide, magnesium-zinc-based ferrite, and nickel-zinc-based ferrite.

31. The laminate sheet as claimed in claim 27, wherein the electromagnetic wave absorber is used in an amount of 1 to 300 parts by weight based on 100 parts by weight of a polymer resin of the polymer resin layer.

32. The laminate sheet as claimed in claim 21, wherein a surface resistance is within a range of 10⁻⁵ to 10⁻⁸ Ω·m at 20° C.

33. A tape for shielding electromagnetic waves, and/or to ground static electricity comprising
a laminate sheet; and
an adhesive layer partially or entirely laminated on one surface of the laminate sheet,
wherein the laminate sheet comprises a polymer resin layer; and at least one metal foil layer laminated on one surface or both surfaces of the polymer resin layer, which is applied to shield electromagnetic waves, and/or to ground static electricity.

34. The tape as claimed in claim 33, wherein multiple embossed portions are formed on one surface or both surfaces of the laminate sheet.

35. The tape as claimed in claim 34, wherein multiple perforated portions are formed, the multiple perforated portions being positioned between the embossed portions and being penetrated in a thickness direction of the laminate sheet.

36. The tape as claimed in claim 33, wherein multiple perforated portions penetrated in a thickness direction of the laminate sheet are formed.

37. A gasket for shielding electromagnetic waves, and/or to ground static electricity comprising
an elastomer core; and
a laminate sheet, the laminate sheet surrounding an outer circumferential surface of the elastomer core,
wherein the laminate sheet comprises a polymer resin layer; and at least one metal foil layer laminated on one surface or both surfaces of the polymer resin layer, which is applied to shield electromagnetic waves, and/or to ground static electricity.

38. The gasket as claimed in claim 37, wherein multiple embossed portions are formed on one surface or both surfaces of the laminate sheet.

39. The gasket as claimed in claim 38, wherein multiple perforated portions are formed, the multiple perforated portions being positioned between the embossed portions and being penetrated in a thickness direction of the laminate sheet.

40. The gasket as claimed in claim 37, wherein multiple perforated portions penetrated in a thickness direction of the laminate sheet are formed.
